(19) United States
(12) Patent Application Publication
(10) Pub. No.: US 2017/0283985 A1
(43) Pub. Date: Oct. 5, 2017

(54) VAPOR PHASE GROWTH APPARATUS AND VAPOR PHASE GROWTH METHOD

(71) Applicant: NuFlare Technology, Inc., Kanagawa (JP)

(72) Inventors: Hideshi TAKAHASHI, Yokohama-shi, Kanagawa (JP); Yuusuke SATO, Bunkyo-ku, Tokyo (JP)

(21) Appl. No.: 15/624,239

(22) Filed: Jun. 15, 2017

Related U.S. Application Data
(63) Continuation of application No. PCT/JP2015/084528, filed on Dec. 9, 2015.

(30) Foreign Application Priority Data
Dec. 17, 2014 (JP) 2014-254658

(51) Int. Cl. C30B 25/14; H01L 21/02; C23C 16/34; C30B 29/40; C23C 16/455

(52) U.S. Cl. CPC C30B 25/14; C30B 29/406; C23C 16/45565; C23C 16/34; H01L 21/0254; H01L 21/0262

(57) ABSTRACT

A vapor phase growth apparatus includes: a reaction chamber; a support provided in the reaction chamber, the support on which a substrate can be placed; a first gas supply passage supplying first gas including ammonia; a second gas supply passage supplying second gas including metal-organic gas; a purge gas supply passage supplying purge gas including ammonia and at least one selected from nitrogen, hydrogen, and inert gas; and a shower head including first region and second region provided around the first region, process gas ejection holes provided in the first region, connected to the first gas supply passage and second gas supply passage and through which the first gas and second gas are supplied into the reaction chamber, a purge gas ejection hole provided in the second region, connected to the purge gas supply passage and through which purge gas is supplied into the reaction chamber.

### CROSS-REFERENCE TO RELATED APPLICATION

This application is based upon and claims the benefit of priority from Japanese Patent Application No. 2014-254658, filed on Dec. 17, 2014, the entire contents of which are incorporated herein by reference.

### FIELD OF THE INVENTION

Embodiments described herein relate generally to a vapor phase growth apparatus and vapor phase growth method for forming a film through the supply of gas.

### BACKGROUND OF THE INVENTION

As a method for forming a high-quality semiconductor film, there is an epitaxial growth technology that makes a single crystal film grown on a substrate, such as a wafer, through vapor phase growth. In a vapor phase growth apparatus using the epitaxial growth technology, a wafer is placed on a support in a reaction chamber kept at normal pressure or reduced pressure. Then, while heating this wafer, the vapor phase growth apparatus supplies process gas such as source gas that is raw material for forming a film from, for example, a shower head located in the upper part of the reaction chamber to the surface of the wafer. A thermal reaction or the like of the source gas is produced on the surface of the wafer, and an epitaxial single crystal film is formed on the surface of the wafer.

In recent years, a GaN (gallium nitride)-based semiconductor device has been drawing attention as material of light emitting devices and power devices. As an epitaxial growth technology for forming a GaN-based semiconductor film, there is metalorganic chemical vapor deposition (MOCVD). In the metalorganic chemical vapor deposition, for example, organic metal such as trimethylgallium (TMG), trimethylindium (TMI), and trimethylaluminum (TMA), ammonia (NH₃), etc. are used as source gas. Furthermore, to suppress the reaction between source gases, hydrogen (H₂) or the like is sometimes used as separation gas.

Then, in the epitaxial growth technology, to reduce particles or the like in a reaction chamber and form a less-defective film, it is preferable to suppress the accumulation of a film on the side wall of the reaction chamber. Accordingly, when a film is formed, purge gas is supplied along the side wall of the reaction chamber.

### SUMMARY OF THE INVENTION

A vapor phase growth apparatus of an embodiment includes: a reaction chamber; a support provided in the reaction chamber, the support on which a substrate can be placed; a first gas supply passage supplying first gas including ammonia; a second gas supply passage supplying second gas including metal-organic gas; a purge gas supply passage supplying purge gas including ammonia and at least one selected from nitrogen, hydrogen, and inert gas; and a shower head including first region and second region provided around the first region, process gas ejection holes provided in the first region, connected to the first gas supply passage and second gas supply passage and through which the first gas and second gas are supplied into the reaction chamber, a purge gas ejection hole provided in the second region, connected to the purge gas supply passage and through which purge gas is supplied into the reaction chamber.

A vapor phase growth method of an embodiment for forming a semiconductor film on a surface of a substrate includes: placing the substrate on a support provided in a reaction chamber; heating the substrate; and while supplying first gas including ammonia and second gas including metal-organic gas from an upper part of the reaction chamber onto the substrate, supplying purge gas including ammonia and at least one selected from nitrogen, hydrogen, and inert gas from the upper part of the reaction chamber to outside of the support along a side wall of the reaction chamber.

### BRIEF DESCRIPTION OF THE DRAWINGS

FIG. 1 is a schematic cross-sectional view of a vapor phase growth apparatus in a first embodiment.

FIG. 2 is a schematic top view of a shower head in the first embodiment.

FIG. 3 is a cross-sectional view of the shower head along the line A-A shown in FIG. 2.

FIGS. 4A to 4C are cross-sectional views of the shower head along the lines B-B, C-C, and D-D shown in FIG. 2, respectively.

FIG. 5 is a schematic bottom view of the shower head in the first embodiment.

FIG. 6 is an explanatory diagram of a vapor phase growth method in the first embodiment.

FIG. 7 is a schematic cross-sectional view of a vapor phase growth apparatus in a second embodiment.

FIG. 8 is a schematic cross-sectional view of a vapor phase growth apparatus in a third embodiment.

FIG. 9 is a schematic cross-sectional view of a vapor phase growth apparatus in a fourth embodiment.

### DETAILED DESCRIPTION OF THE EMBODIMENTS

Embodiments of the present invention are described below by reference to drawings.

Incidentally, in the present specification, a vertical direction in a state where a vapor phase growth apparatus is installed so as to be able to form a film is defined as “down,” and its opposite direction is defined as “up.” Therefore, “the lower part” means the position in the vertical direction with respect to a reference point, and “below” means the vertical direction with respect to the reference point. Then, “the upper part” means the position in the opposite direction of the vertical direction with respect to a reference point, and “above” means the opposite direction of the vertical direction with respect to the reference point. Furthermore, a “longitudinal direction” is the vertical direction.

Moreover, in the present specification, a “horizontal plane” shall mean a plane perpendicular to the vertical direction.

Furthermore, in the present specification, “process gas” is the general term for gas used for forming a film on a substrate, and shall be the concept including, for example, source gas, carrier gas, separation gas, and the like.

Moreover, in the present specification, “purge gas” means gas supplied to the side of the outer circumference of a substrate along the side wall of a reaction chamber in order to suppress the accumulation of a film on the inner surface of the side wall (the inner wall) of the reaction chamber during the film formation.

### First Embodiment

A vapor phase growth apparatus in the present embodiment includes a reaction chamber; a support provided in the reaction chamber, the support on which a substrate can be placed; a first gas supply passage supplying first gas including ammonia; a second gas supply passage supplying second gas including metal-organic gas; a purge gas supply passage supplying purge gas including ammonia and at least one selected from nitrogen, hydrogen, and inert gas; and a shower head including first region and second region provided around the first region, process gas ejection holes provided in the first region, connected to the first gas supply passage and second gas supply passage and through which the first gas and second gas are supplied into the reaction chamber, a purge gas ejection hole provided in the second region, connected to the purge gas supply passage and through which purge gas is supplied into the reaction chamber.

The case where GaN (gallium nitride) or InGaN (indium gallium nitride) is epitaxially grown by using MOCVD (metalorganic chemical vapor deposition) is described below as an example.

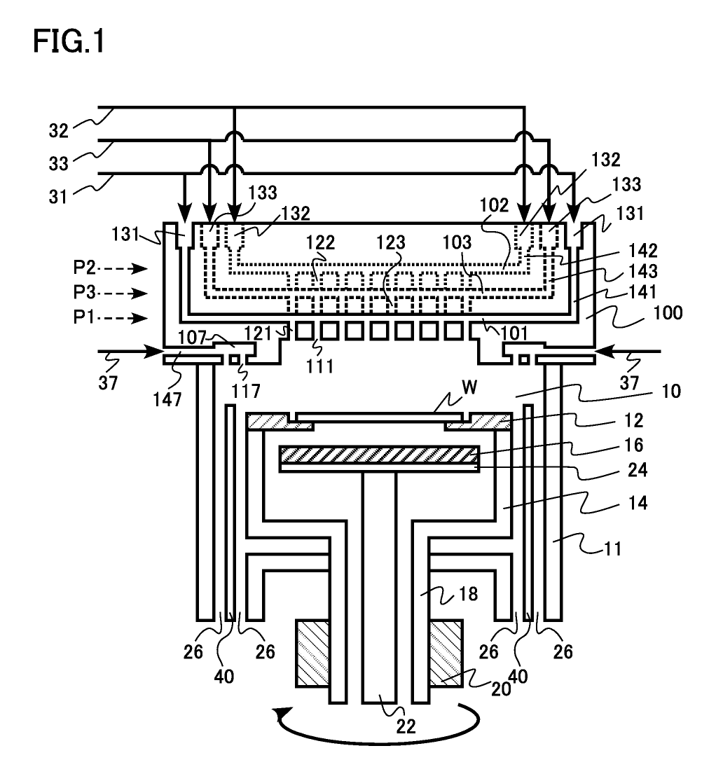

FIG. 1 is a schematic cross-sectional view of the vapor phase growth apparatus in the present embodiment. The vapor phase growth apparatus in the present embodiment is a single wafer type epitaxial growth apparatus.

As shown in FIG. 1, the vapor phase growth apparatus in the present embodiment includes a reaction chamber 10 that is a cylindrical hollow body made of, for example, aluminum or stainless steel. The side surface of the reaction chamber 10 is a side wall 11. Then, the vapor phase growth apparatus includes a shower head 100 that is disposed in the upper part of the reaction chamber 10 to supply process gas into the reaction chamber 10.

Furthermore, the vapor phase growth apparatus includes a support 12 that is provided within the reaction chamber 10 below the shower head 100, and on which a semiconductor wafer (a substrate) W can be placed. The support 12 is, for example, an annular holder provided with an opening in the center or a susceptor structured to be in contact with almost the whole area of the back surface of the semiconductor wafer W.

Moreover, the vapor phase growth apparatus includes a rotating body unit 14 and a heater as a heating unit 16 below the support 12; the rotating body unit 14 rotates with the support 12 disposed on the top thereof, and the heating unit 16 heats a wafer W placed on the support 12. Here, a rotating shaft 18 of the rotating body unit 14 is connected to a rotary drive mechanism 20 located below. Then, the semiconductor wafer W can be rotated at, for example, 50 rpm or more but not exceeding 3000 rpm with the wafer center as the rotation center by the rotary drive mechanism 20.

It is preferable that the diameter of the cylindrical rotating body unit 14 is about the same as the outer circumferential diameter of the support 12. Incidentally, the rotating shaft 18 is rotatably provided on the bottom of the reaction chamber 10 through a vacuum sealing member.

Then, the heating unit 16 is fixedly provided on a support table 24 fixed to a support shaft 22 that penetrates the inside of the rotating shaft 18. Electric power is supplied to the heating unit 16 by a current introduction terminal (not shown) and electrodes (not shown). This support table 24 is provided with, for example, a push up pin (not shown) for removing the semiconductor wafer W from the support 12.

A reflector 40 is provided around the support 12 inside the reaction chamber 10. The reflector 40 reflects heat applied by the heating unit 16 and suppresses the transmission of the heat to the side wall 11 in order to efficiently heat the substrate W. It is preferable that the reflector 40 is made by using, for example, quartz.

Furthermore, the vapor phase growth apparatus includes a gas discharger as a gas discharge unit 26 on the bottom of the reaction chamber 10; the gas discharge unit 26 discharges a reaction product after the reaction of source gas on the surface of the semiconductor wafer W or elsewhere and residual gas in the reaction chamber 10 to the outside of the reaction chamber 10. Incidentally, the gas discharge unit 26 is connected to a vacuum pump (not shown).

Then, the vapor phase growth apparatus in the present embodiment includes a first gas supply passage 31 supplying first process gas (first gas), a second gas supply passage 32 supplying second process gas (second gas), and a third gas supply passage 33 supplying third process gas (third gas).

Furthermore, the vapor phase growth apparatus includes a purge gas supply passage 37 for supplying purge gas including at least one selected from nitrogen, hydrogen, and inert gas and ammonia.

In the case where a GaN single crystal film is formed on a semiconductor wafer W by the MOCVD, for example, ammonia (NH₃) which serves as source gas of nitrogen is supplied as first process gas (first gas). Furthermore, for example, gas obtained by diluting trimethylgallium (TMG), which serves as source gas of Ga (gallium) and is organic metal, with hydrogen (H₂), which is carrier gas, is supplied as second process gas (second gas). Moreover, as third process gas, for example, hydrogen (H₂) is supplied as separation gas. Incidentally, as carrier gas or separation gas, nitrogen (N₂) or mixed gas of nitrogen and hydrogen can be used.

Furthermore, in the case where an InGaN single crystal film is formed on a semiconductor wafer W by the MOCVD, for example, ammonia (NH₃) which serves as source gas of nitrogen (N) is supplied as first process gas (first gas). Furthermore, for example, gas obtained by diluting trimethylgallium (TMG), which serves as source gas of Ga (gallium) and is organic metal, and trimethylindium (TMI), which serves as source gas of In (indium) and is organic metal, with nitrogen (N₂), which is carrier gas, is supplied as second process gas (second gas). Moreover, as third process gas, for example, nitrogen (N₂) is supplied as separation gas.

The separation gas serving as third process gas (third gas) here is the gas that is ejected from a third gas ejection hole 113, thereby separating into first process gas ejected from a first gas ejection hole 111 and second process gas ejected from a second gas ejection hole 112. As the separation gas, it is preferable to use gas that is poorly responsive to the first process gas and the second process gas.

For example, in the case where a GaN single crystal film is formed on a semiconductor wafer W, purge gas includes first purge gas component gas, including at least one selected from nitrogen (N₂) with a molecular weight of 28, hydrogen (H₂) with a molecular weight of 2, and inert gas such as helium (He) with an atomic weight of 4 or argon (Ar) with an atomic weight of 40, and second purge gas component gas, including ammonia (NH₃) with a molecular weight of 17.

Furthermore, for example, in the case where an InGaN single crystal film is formed on a semiconductor wafer W, purge gas includes first purge gas component gas, including at least one selected from nitrogen (N₂) and inert gas, and second purge gas component gas, including ammonia (NH₃). Accordingly, the average molecular weight of purge gas can be appropriately set according to the average molecular weight of process gas.

Incidentally, in the single wafer type epitaxial growth apparatus shown in FIG. 1, the side wall 11 of the reaction chamber 10 is provided with a wafer inlet/outlet (not shown) and a gate valve (not shown) for taking a semiconductor wafer in and out. Then, the single wafer type epitaxial growth apparatus is configured so that a semiconductor wafer W can be transferred between, for example, a load lock chamber (not shown) and the reaction chamber 10 that are joined by this gate valve by a handling arm. Here, the handling arm formed of, for example, synthetic quartz can be inserted into a space between the shower head 100 and the wafer support 12.

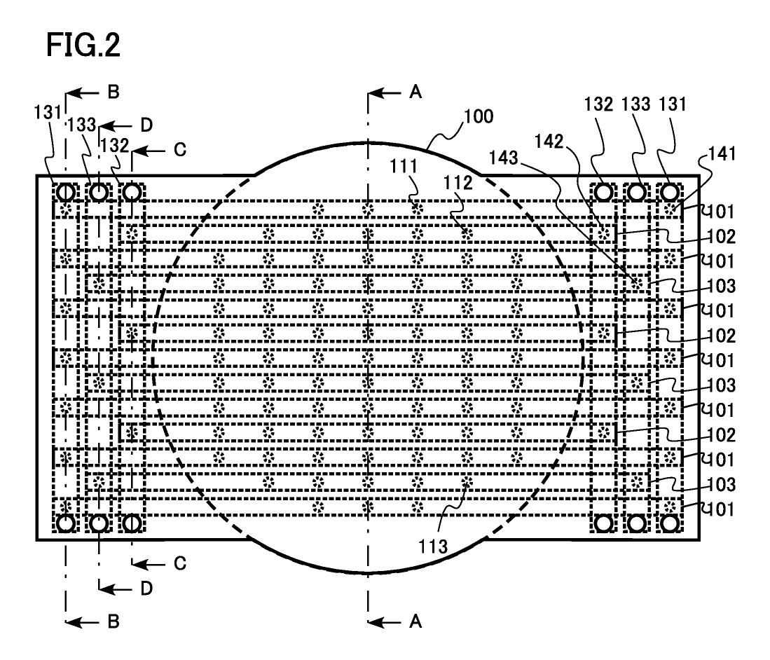

The shower head 100 in the present embodiment is explained in detail below. FIG. 2 is a schematic top view of the shower head in the present embodiment. The structure of the flow channel inside the shower head is indicated by broken lines.

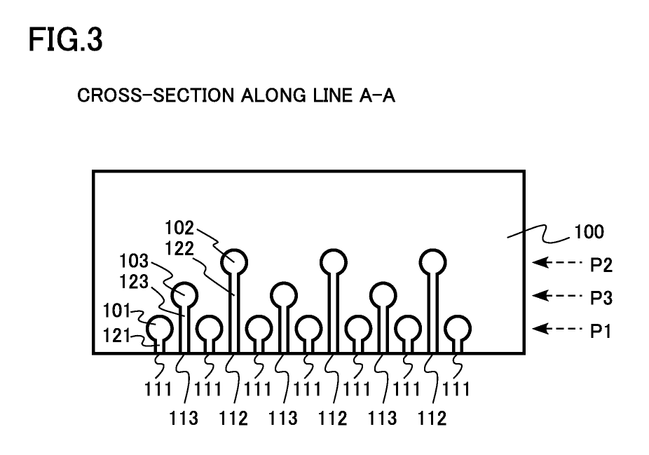

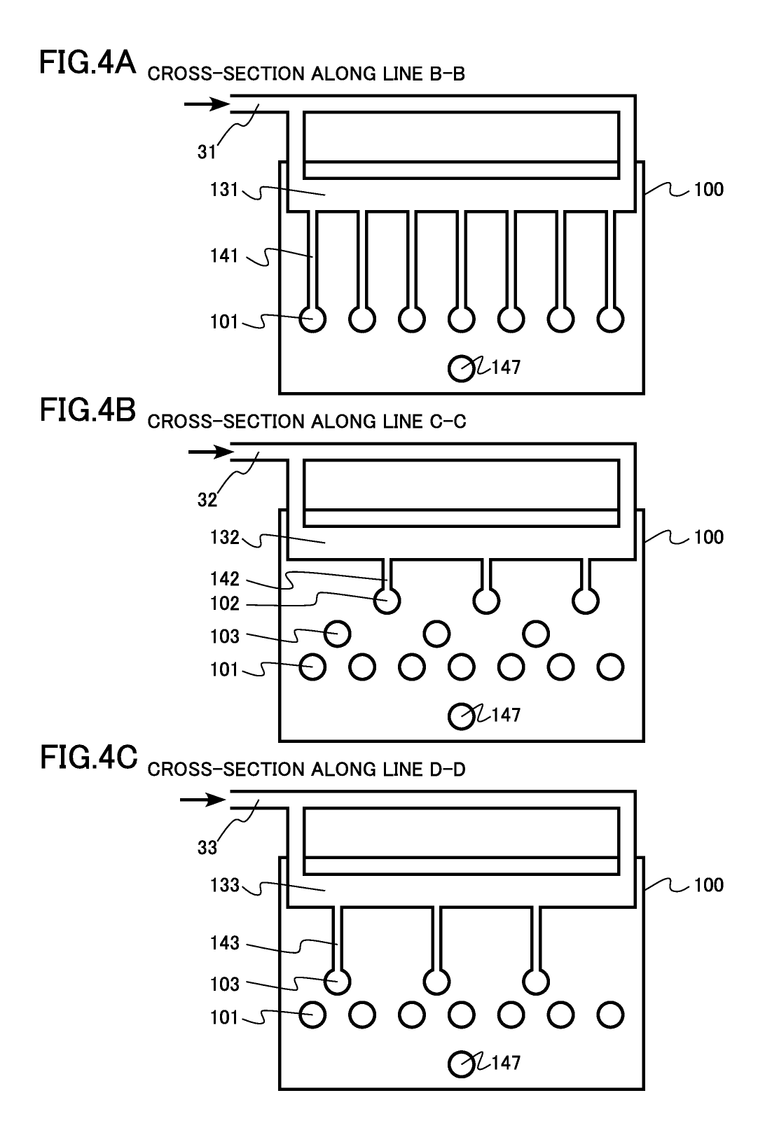

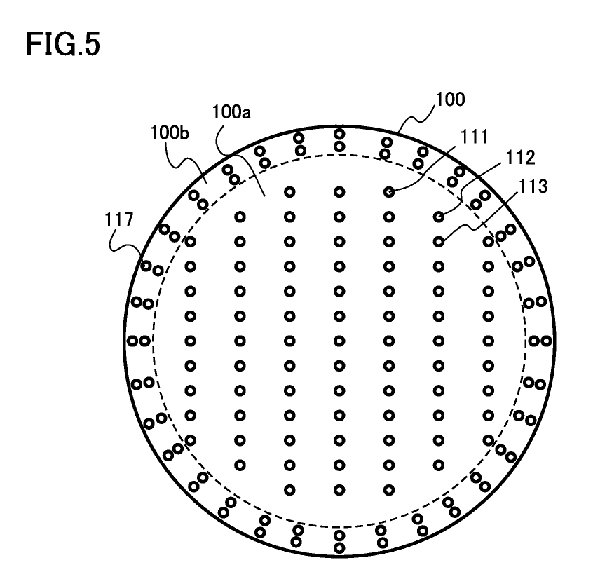

FIG. 3 is a cross-sectional view of the shower head along the line A-A shown in FIG. 2; FIGS. 4A to 4C are cross-sectional views of the shower head along the lines B-B, C-C, and D-D shown in FIG. 2, respectively. FIG. 5 is a schematic bottom view of the shower head in the present embodiment.

The shower head 100 has, for example, a plate-like shape with a predetermined thickness. The shower head 100 is formed of, for example, metal material such as stainless steel or aluminum alloy.

Inside the shower head 100, a plurality of first lateral gas flow channels 101, a plurality of second lateral gas flow channels 102, and a plurality of third lateral gas flow channels 103 are formed. The first lateral gas flow channels 101 are disposed in a first horizontal plane (P1) and extend parallel to one another. The second lateral gas flow channels 102 are disposed in a second horizontal plane (P2) above the first horizontal plane and extend parallel to one another. The third lateral gas flow channels 103 are disposed in a third horizontal plane (P3) that is above the first horizontal plane and below the second horizontal plane, and extend parallel to one another.

Then, the shower head 100 includes a plurality of first longitudinal gas flow channels 121 that are connected to the first lateral gas flow channels 101 and extend in the longitudinal direction, and each have the first gas ejection hole 111 on the side of the reaction chamber 10. Furthermore, the shower head 100 includes a plurality of second longitudinal gas flow channels 122 that are connected to the second lateral gas flow channels 102 and extend in the longitudinal direction, and each have the second gas ejection hole 112 on the side of the reaction chamber 10. The second longitudinal gas flow channels 122 each run between the two first lateral gas flow channels 101. Moreover, the shower head 100 includes a plurality of third longitudinal gas flow channels 123 that are connected to the third lateral gas flow channels 103 and extend in the longitudinal direction, and each have the third gas ejection hole 113 on the side of the reaction chamber 10. The third longitudinal gas flow channels 123 run between the first lateral gas flow channels 101.

The first lateral gas flow channels 101, the second lateral gas flow channels 102, and the third lateral gas flow channels 103 are lateral holes formed in a horizontal direction in the plate-like shower head 100. Furthermore, the first longitudinal gas flow channels 121, the second longitudinal gas flow channels 122, and the third longitudinal gas flow channels 123 are longitudinal holes formed in the vertical direction (the longitudinal direction or a perpendicular direction) in the plate-like shower head 100.

The respective inner diameters of the first, second, and third lateral gas flow channels 101, 102, and 103 are larger than the inner diameters of the corresponding first, second, and third longitudinal gas flow channels 121, 122, and 123. In FIGS. 3 and 4(a) to 4(c), the cross-sectional shapes of the first, second, and third lateral gas flow channels 101, 102, and 103 and the first, second, and third longitudinal gas flow channels 121, 122, and 123 are all circular; however, the cross-sectional shapes of them are not limited to be circular, and can be other shapes, such as oval, rectangular, and polygonal. Furthermore, the cross-sectional areas of the first, second, and third lateral gas flow channels 101, 102, and 103 do not have to be the same. Moreover, the cross-sectional areas of the first, second, and third longitudinal gas flow channels 121, 122, and 123 also do not have to be the same.

The shower head 100 includes a first manifold 131, which is connected to the first gas supply passage 31 and is provided above the first horizontal plane (P1), and a first connection flow channel 141 which connects the first manifold 131 and the first lateral gas flow channels 101 at the ends of the first lateral gas flow channels 101 and extends in the longitudinal direction.

The first manifold 131 has a function of distributing first process gas supplied from the first gas supply passage 31 to the first lateral gas flow channels 101 through the first connection flow channel 141. The distributed first process gas is introduced from the first gas ejection holes 111 of the first longitudinal gas flow channels 121 into the reaction chamber 10.

The first manifold 131 extends in a direction perpendicular to the first lateral gas flow channels 101, and has a shape of, for example, a hollow rectangular parallelepiped. In the present embodiment, the first manifold 131 is provided on both ends of the first lateral gas flow channels 101; however, the first manifold 131 can be provided on either one end.

Furthermore, the shower head 100 includes a second manifold 132, which is connected to the second gas supply passage 32 and is provided above the first horizontal plane (P1), and a second connection flow channel 142 which connects the second manifold 132 and the second lateral gas flow channels 102 at the ends of the second lateral gas flow channels 102 and extends in the longitudinal direction.

The second manifold 132 has a function of distributing second process gas supplied from the second gas supply passage 32 to the second lateral gas flow channels 102 through the second connection flow channel 142. The distributed second process gas is introduced from the second gas ejection holes 112 of the second longitudinal gas flow channels 122 into the reaction chamber 10.

The second manifold 132 extends in a direction perpendicular to the second lateral gas flow channels 102, and has a shape of, for example, a hollow rectangular parallelepiped. In the present embodiment, the second manifold 132 is provided on both ends of the second lateral gas flow channels 102; however, the second manifold 132 can be provided on either one end.

Moreover, the shower head 100 includes a third manifold 133, which is connected to the third gas supply passage 33 and is provided above the first horizontal plane (P1), and a third connection flow channel 143 which connects the third manifold 133 and the third lateral gas flow channels 103 at the ends of the third lateral gas flow channels 103 and extends in the perpendicular direction.

The third manifold 133 has a function of distributing third process gas supplied from the third gas supply passage 33 to the third lateral gas flow channels 103 through the third connection flow channel 143. The distributed third process gas is introduced from the third gas ejection holes 113 of the third longitudinal gas flow channels 123 into the reaction chamber 10.

Furthermore, as shown in FIG. 5, the shower head 100 is divided into an inner region 100a where the first to third gas ejection holes 111 to 113 are provided and an outer region 100b where purge gas ejection holes 117 through which purge gas is ejected are provided. The purge gas ejection holes 117 are provided along the side wall 11 of the reaction chamber 10 than the first to third gas ejection holes 111 to 113 are.

The purge gas ejection holes 117 are connected to a lateral purge gas flow channel 107. The purge gas flow channel 107 is formed as a ring-like hollow part within the outer region 100b of the shower head 100. Then, the lateral purge gas flow channel 107 is connected to a purge gas connection flow channel 147. Furthermore, the purge gas supply passage 37 is connected to the purge gas connection flow channel 147. Therefore, the purge gas supply passage 37 is connected to the purge gas ejection holes 117 through the purge gas connection flow channel 147 and the lateral purge gas flow channel 107.

Incidentally, in FIGS. 4A to 4C, the cross-sectional shape of the purge gas connection flow channel 147 is circular; however, the cross-sectional shape of the purge gas connection flow channel 147 is not limited to be circular, and can be other shapes, such as oval, rectangular, and polygonal.

It is preferable that the flow rate of process gas ejected from a gas ejection hole provided on the shower head as a supply port of process gas into the reaction chamber 10 is uniform among the gas ejection holes in terms of ensuring the uniformity of film formation. According to the shower head 100 in the present embodiment, process gas is distributed to a plurality of lateral gas flow channels, and further distributed to longitudinal gas flow channels and ejected from gas ejection holes. By this configuration, the uniformity of the flow rate of process gas ejected from each gas ejection hole can be improved with a simple structure.

Furthermore, it is preferable that the disposition density of disposed gas ejection holes is as high as possible in terms of performing the uniform film formation. Though, in a configuration in which a plurality of lateral gas flow channels parallel to one another are provided like the present embodiment, if the density of gas ejection holes is increased, trade-off is generated between the disposition density of the gas ejection holes and the inner diameter of the lateral gas flow channels.

Accordingly, the inner diameter of the lateral gas flow channels becomes small, which increases the flow resistance of the lateral gas flow channels, and, in an extending direction of the lateral gas flow channels, the flow rate distribution of the flow rate of process gas ejected from the gas ejection holes becomes larger, and the uniformity of the flow rate of process gas ejected from each gas ejection hole maybe worsened.

According to the shower head in the present embodiment, there is adopted a hierarchic structure in which the first lateral gas flow channels 101, the second lateral gas flow channels 102, and the third lateral gas flow channels 103 are provided on different horizontal planes. This structure improves a margin for an increase in the inner diameter of the lateral gas flow channels. Therefore, while increasing the density of the gas ejection holes, the expansion of the flow rate distribution caused by the inner diameter of the lateral gas flow channels is suppressed.

Subsequently, a vapor phase growth method in the present embodiment is described. The vapor phase growth method in the present embodiment is, the vapor phase growth method in the embodiment is that a substrate is placed on the support provided in the reaction chamber, and the substrate is heated, and then while supplying first gas including ammonia and second gas including at least one selected from trimethylgallium and trimethylindium that are metal-organic gas from the upper part of the reaction chamber onto the substrate, purge gas including ammonia and at least one selected from nitrogen, hydrogen, and inert gas is supplied from the upper part of the reaction chamber to outside of the support along a side wall of the reaction chamber, thereby a semiconductor film is formed on the surface of the substrate.

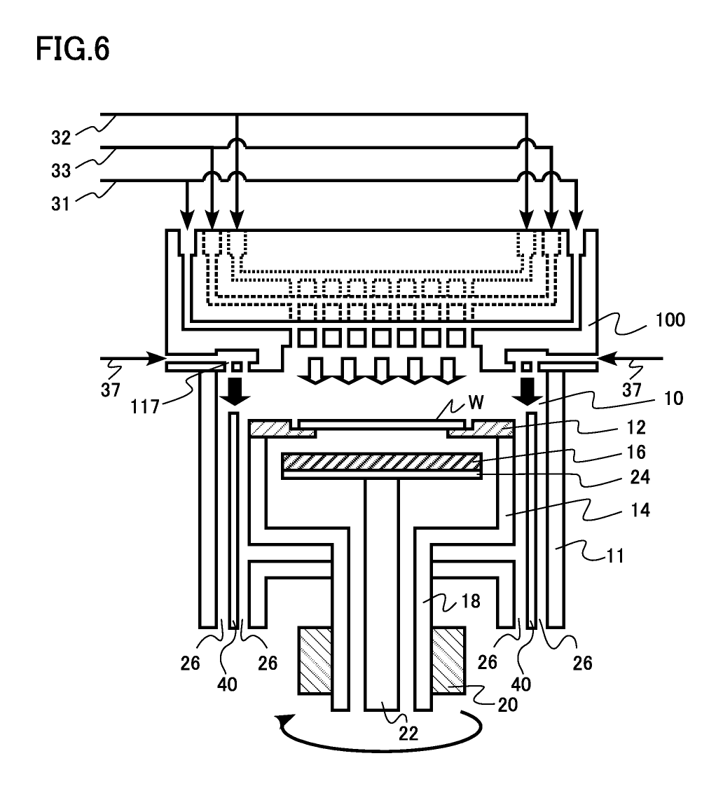

The case where GaN or InGaN is epitaxially grown by using the vapor phase growth apparatus shown in FIGS. 1 to 5 is described below as an example. FIG. 6 is an explanatory diagram of the vapor phase growth method in the present embodiment.

In a state where the reaction chamber 10 is controlled at predetermined pressure by supplying carrier gas such as H₂ to the reaction chamber 10 and discharging gas in the reaction chamber 10 from the gas discharge unit 26 by running the vacuum pump (not shown), a semiconductor wafer W is placed on the support 12 in the reaction chamber 10. Here, for example, the gate valve (not shown) of the wafer inlet/outlet of the reaction chamber 10 is open, and the semiconductor wafer W in the load lock chamber is transferred into the reaction chamber 10 by the handling arm. Then, the semiconductor wafer W is placed on the support 12 through, for example, a push up pin (not shown), and the handling arm is placed back to the load lock chamber, and then the gate valve is closed.

The semiconductor wafer W placed on the support 12 is preheated at a predetermined temperature by the heating unit 16. Further, the temperature of the semiconductor wafer W is risen to an epitaxial growth temperature by increasing the heating power of the heating unit 16. Also during the temperature rising, the reaction chamber 10 is supplied with, for example, H₂.

Then, the exhaust ventilation by the above-described vacuum pump is continued, and, while rotating the rotating body unit 14 at predetermined speed, predetermined first to third process gases (white arrows in FIG. 6) are ejected from the first to third gas ejection holes 111, 112, and 113. The first process gas (first gas) is ejected from the first gas supply passage 31, through the first manifold 131, the first connection flow channel 141, the first lateral gas flow channels 101, and the first longitudinal gas flow channels 121, into the reaction chamber 10 from the first gas ejection holes 111. Furthermore, the second process gas (second gas) is ejected from the second gas supply passage 32, through the second manifold 132, the second connection flow channel 142, the second lateral gas flow channels 102, and the second longitudinal gas flow channels 122, into the reaction chamber 10 from the second gas ejection holes 112. Moreover, the third process gas is ejected from the third gas supply passage 33, through the third manifold 133, the third connection flow channel 143, the third lateral gas flow channels 103, and the third longitudinal gas flow channels 123, into the reaction chamber 10 from the third gas ejection holes 113.

Further, first to third process gases are ejected, and at the same time, purge gas adjusted to be brought close to the average molecular weight of process gas is ejected from the purge gas ejection holes 117 at the predetermined flow velocity and flow rate (black arrows in FIG. 6).

In the case where GaN is epitaxially grown, after a wafer is heated to a growth temperature of GaN film by controlling the heating unit 16, ammonia is supplied to the first gas ejection holes 111, and TMG is supplied to the second gas ejection holes 112. Accordingly, a GaN single crystal film is formed on the surface of the semiconductor wafer W by the epitaxial growth.

Furthermore, in the case where InGaN is epitaxially grown, after a wafer is heated to a growth temperature of InGaN by controlling the heating unit 16, ammonia is supplied to the first gas ejection holes 111, and TMG and TMI are supplied to the second gas ejection holes 112, thereby an InGaN single crystal film is formed on the surface of the semiconductor wafer W by the epitaxial growth.

Then, at the completion of the epitaxial growth, the supply of TMG and TMI to the second gas ejection holes 113 is stopped, and the growth of the single crystal film is completed.

After the formation of the film, the temperature of the semiconductor wafer W starts dropping. When the temperature of the semiconductor wafer W has decreased to a predetermined temperature, the supply of ammonia to the second gas ejection holes 112 is stopped. Here, for example, the number of revolutions of the rotating body unit 14 is reduced, and while the semiconductor wafer W with the single crystal film formed thereon remains on the support 12, the heating power of the heating unit 16 is restored to the initial state so that the temperature of the semiconductor wafer W is adjusted to decrease to the preheat temperature.

Then, after the semiconductor wafer W has become stable at the predetermined temperature, the semiconductor wafer W is removed from the support 12, for example, by the push up pin. Then, the gate valve is again open, and the handling arm is inserted between the shower head 100 and the support 12, and then the semiconductor wafer W is placed on top of the handling arm. Then, the handling arm with the semiconductor wafer W placed thereon is placed back to the load lock chamber.

One formation of a film on the semiconductor wafer W is completed as described above, and, for example, the formation of a film on another semiconductor wafer W can also be continuously performed in accordance with the above-described process sequence.

As described above, by bringing the average molecular weight of purge gas close to the average molecular weight of process gas, the flow turbulence at the boundary between purge gas and process gas is suppressed, and the film accumulation on the side wall 11 in the reaction chamber 10 is suppressed. Particularly, by using ammonia with a molecular weight of 17 that has a molecular weight between hydrogen with a molecular weight of 2 and nitrogen with a molecular weight of 28, the flow turbulence at the boundary between the two is further suppressed, and the film accumulation on the side wall 11 in the reaction chamber 10 is suppressed. Furthermore, from a relationship of dynamic viscosity among hydrogen, nitrogen, and ammonia, the film accumulation on the side wall 11 in the reaction chamber 10 is estimated to be further suppressed.

In the case where an InGaN single crystal film is formed on a semiconductor wafer W, by using H₂ in purge gas, In becomes less likely to be taken in the film on the semiconductor wafer W. Accordingly, in the case where second gas includes trimethylindium, it is preferable that purge gas includes ammonia and nitrogen; in the case where second gas does not include trimethylindium, it is preferable that purge gas includes ammonia, nitrogen, and hydrogen.

Furthermore, as for purge gas, premixed gas of first purge gas component gas and second purge gas component gas can be supplied to the purge gas supply passage 37 and then supplied into the reaction chamber 10 from the purge gas ejection holes 117. Or, gases composing purge gas can be separately supplied into the reaction chamber 10. However, supplying premixed gas of gases composing purge gas into the reaction chamber 10 from the purge gas ejection holes 117 is more preferable in the way that the structure of the shower head 100 is simplified.

It is preferable that the reflector 40 provided around the support 12 is made by using quartz; alternatively, silicon carbide (SiC) having great heat-resistance can be used. Generally, silicon carbide is porous, and therefore is problematic in terms of impurity adsorption; however, like the present embodiment, by introducing ammonia to a direction of the side wall of the reaction chamber 10, a nitride film is formed on the surface of the reflector 40. Accordingly, it is possible to prevent the deterioration of film quality due to desorption of adsorbed gas.

In terms of bringing the average molecular weight of the first, second, and third process gases flowed to form a film close to the average molecular weight of purge gas, it is preferable that the average molecular weight of purge gas is about the same as the average molecular weight of process gas, and the average flow velocity of purge gas is about the same as the average flow velocity of process gas. If the average molecular weight of mixed gas is 80% or more but not exceeding 120% of the average molecular weight of process gas, the flow turbulence at the boundary between purge gas and process gas is less likely to occur, and which is preferable.

According to the vapor phase growth apparatus and the vapor phase growth method in the present embodiment, the film accumulation on the side wall of the reaction chamber is suppressed by bringing the average molecular weight of process gases to that of purge gas. Therefore, the generation of particles and dust in the reaction chamber is suppressed. Accordingly, a less-defective film can be formed on a substrate.

### Second Embodiment

A vapor phase growth apparatus in the present embodiment is similar to the first embodiment, except that the vapor phase growth apparatus in the present embodiment further includes a first sub purge gas supply passage that is connected to the purge gas supply passage, and includes a first mass flow controller, and supplies first purge gas; a second sub purge gas supply passage that is connected to the purge gas supply passage, and includes a second mass flow controller, and supplies second purge gas; a third sub purge gas supply passage that is connected to the purge gas supply passage, and includes a third mass flow controller, and supplies third purge gas; a fourth sub purge gas supply passage that is connected to the purge gas supply passage, and includes a fourth mass flow controller, and supplies fourth purge gas; a fifth sub purge gas supply passage that is connected to the purge gas supply passage, and includes a fifth mass flow controller, and supplies fifth purge gas; and a first control unit that controls the first mass flow controller, the second mass flow controller, the third mass flow controller, the fourth mass flow controller, and the fifth mass flow controller. Therefore, description of contents overlapping with the first embodiment is omitted.

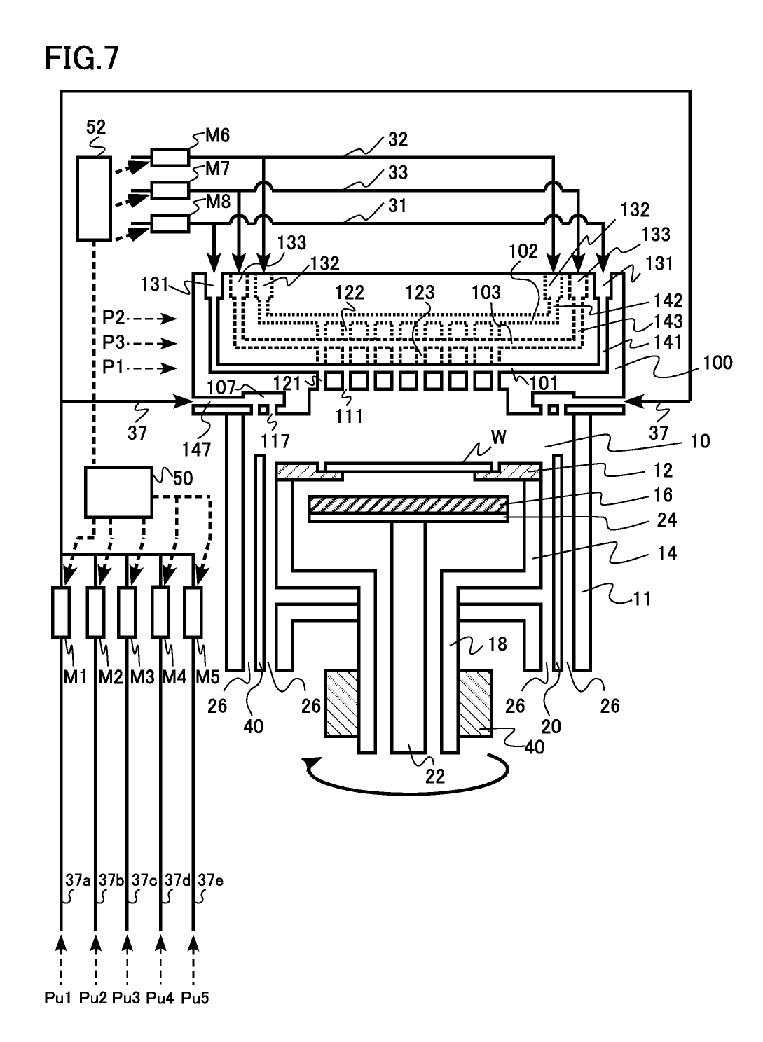

FIG. 7 is a schematic cross-sectional view of the vapor phase growth apparatus in the present embodiment. The vapor phase growth apparatus in the present embodiment is a single wafer type epitaxial growth apparatus.

As shown in FIG. 7, the vapor phase growth apparatus in the present embodiment includes a first sub purge gas supply passage 37a that is connected to the purge gas supply passage 37 and includes a first mass flow controller M1; a second sub purge gas supply passage 37b that is connected to the purge gas supply passage 37 and includes a second mass flow controller M2; a third sub purge gas supply passage 37c that is connected to the purge gas supply passage 37 and includes a third mass flow controller M3; a fourth sub purge gas supply passage 37d that is connected to the purge gas supply passage 37 and includes a fourth mass flow controller M4; a fifth sub purge gas supply passage 37e that is connected to the purge gas supply passage 37 and includes a fifth mass flow controller M5; and a first control unit 50 that controls the first mass flow controller M1, the second mass flow controller M2, the third mass flow controller M3, the fourth mass flow controller M4, and the fifth mass flow controller M5.

The first sub purge gas supply passage 37a supplies first purge gas (Pu1). The flow rate of first purge gas is controlled by the first mass flow controller M1. Furthermore, the second sub purge gas supply passage 37b supplies second purge gas (Pu2). The flow rate of second purge gas is controlled by the second mass flow controller M2. Moreover, the third sub purge gas supply passage 37c supplies third purge gas (Pu3). The flow rate of third purge gas is controlled by the third mass flow controller M3. Furthermore, the fourth sub purge gas supply passage 37d supplies fourth purge gas (Pu4). The flow rate of fourth purge gas is controlled by the fourth mass flow controller M4. Moreover, the fifth sub purge gas supply passage 37e supplies fifth purge gas (Pu5). The flow rate of fifth purge gas is controlled by the fifth mass flow controller M5. The flow rates of the first purge gas, the second purge gas, the third purge gas, the fourth purge gas, and the fifth purge gas are controlled by the first mass flow controller M1, the second mass flow controller M2, the third mass flow controller M3, the fourth mass flow controller M4, and the fifth mass flow controller M5, respectively, and these first to fifth purge gases are mixed and become mixed gas.

The first control unit 50 controls the first mass flow controller M1, the second mass flow controller M2, the third mass flow controller M3, the fourth mass flow controller M4, and the fifth mass flow controller M5, for example, by transmitting a control signal. Accordingly, the flow rate of the first purge gas, the flow rate of the second purge gas, the flow rate of the third purge gas, the flow rate of the fourth purge gas, and the flow rate of the fifth purge gas are changed, and the average molecular weight of the purge gases supplied to the reaction chamber 10 is changed.

When the average molecular weight of process gas has been changed by a change in type or the like of process gas supplied to the reaction chamber 10 during a film formation process, the first control unit 50 changes the average molecular weight of the purge gases so as to be brought close to the average molecular weight of the process gas.

In the case where GaN is grown on a substrate, for example, nitrogen is supplied by using the first sub purge gas supply passage 37a; hydrogen is supplied by using the second sub purge gas supply passage 37b; helium that is inert gas is supplied by using the third sub purge gas supply passage 37c; argon that is inert gas is supplied by using the fourth sub purge gas supply passage 37d; and ammonia is supplied by using the fifth sub purge gas supply passage 37e.

For example, first purge gas component gases can be mixed by using the first sub purge gas supply passage 37a, the second sub purge gas supply passage 37b, the third sub purge gas supply passage 37c, and the fourth sub purge gas supply passage 37d. Furthermore, second purge gas component gases can be mixed by using the fifth sub purge gas supply passage 37e.

Furthermore, in the case where InGaN is grown continuously afterward, for example, nitrogen is supplied by using the first sub purge gas supply passage 37a; helium is supplied by using the third sub purge gas supply passage 37c; argon is supplied by using the fourth sub purge gas supply passage 37d; and ammonia is supplied by using the fifth sub purge gas supply passage 37e. The average molecular weight of the purge gases is changed in a direction of being brought close to the average molecular weight of process gas used for the formation of a GaN film or the formation of an InGaN film.

A second control unit 52 controls a sixth mass flow controller M6, a seventh mass flow controller M7, and an eighth mass flow controller M8 which are provided on the first gas supply passage 31, the second gas supply passage 32, and the third gas supply passage 33, respectively, for example, by transmitting a control signal. Accordingly, the flow rates of first gas, second gas, and third gas are controlled.

The first control unit 50 and the second control unit 52 are connected to each other, and can be configured to simultaneously control the first mass flow controller M1, the second mass flow controller M2, the third mass flow controller M3, the fourth mass flow controller M4, the fifth mass flow controller M5, the sixth mass flow controller, the seventh mass flow controller, and the eighth mass flow controller. By this configuration, for example, the flow rate of process gas and the flow rate of purge gas are controlled in conjunction. By this control, the average molecular weight of purge gas can be changed in conjunction with a change in the average molecular weight of process gas.

Furthermore, either the first control unit 50 or the second control unit 52 can be connected to the first mass flow controller M1, the second mass flow controller M2, the third mass flow controller M3, the fourth mass flow controller M4, the fifth mass flow controller M5, the sixth mass flow controller, the seventh mass flow controller, and the eighth mass flow controller and control the eight mass flow controllers.

Incidentally, the first control unit 50 and the second control unit 52 may be hardware, such as an electric circuit or a quantum circuit, or may be software. When the first control unit 50 and the second control unit 52 are software, a microprocessor, such as a central processing unit (CPU), a read only memory (ROM) that stores a processing program, a random access memory (RAM) that temporarily stores data, an input/output port, and a communication port may be used. A recording medium is not limited to a detachable recording medium, such as a magnetic disk or an optical disk, and may be a fixed recording medium, such as a hard disk drive or a memory.

Furthermore, the configuration of purge gas can be appropriately selected; for example, the third and fourth sub purge gas supply passages for supplying inert gas and the third and fourth mass flow controllers for controlling their flow rates do not always have to be provided.

According to the present embodiment, the same effects as the first embodiment can be achieved, and also the average molecular weight of purge gas can be easily controlled. Furthermore, even if the average molecular weight of process gas is changed during a film formation process, the average molecular weight of purge gas can also be changed in a direction of having the same average molecular weight as process gas. Therefore, the film accumulation on the side wall of the reaction chamber is suppressed, and the generation of particles and dust in the reaction chamber is suppressed. Accordingly, a less-defective film can be formed on a substrate.

### Third Embodiment

A vapor phase growth apparatus in the present embodiment is similar to the vapor phase growth apparatuses in the first and second embodiments, except that the vapor phase growth apparatus in the present embodiment further includes a first lateral-gas-flow-channels connecting flow channel, which connects a first lateral gas flow channel and a third lateral gas flow channel, and a second lateral-gas-flow-channels connecting flow channel, which connects a second lateral gas flow channel and the third lateral gas flow channel. Therefore, description of contents overlapping with the first and second embodiments is omitted.

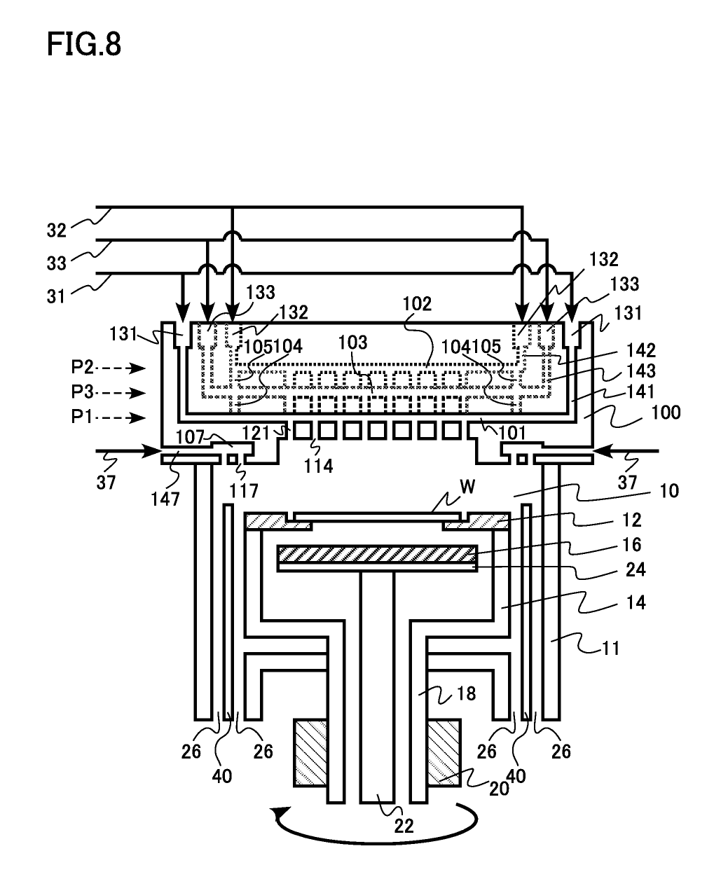

FIG. 8 is a schematic cross-sectional view of the vapor phase growth apparatus in the present embodiment.

In the present embodiment, a first lateral-gas-flow-channels connecting flow channel 104, which connects the first lateral gas flow channel 101 and the third lateral gas flow channel 103, and a second lateral-gas-flow-channels connecting flow channel 105, which connects the second lateral gas flow channel 102 and the third lateral gas flow channel 103, are further provided. Accordingly, the first process gas (first gas), the second process gas (second gas), and the third process gas (third gas) are mixed in the shower head 100, and the mixed gas is supplied from a fourth gas ejection hole 114 to the reaction chamber.

According to the present embodiment, even in the case where, after gases composing process gas are mixed, the mixed gas is uniformly supplied onto a substrate W, the same effects as the first embodiment can be achieved. Furthermore, by providing sub purge gas supply passages like the second embodiment, the same effects as the second embodiment can be achieved.

### Fourth Embodiment

A vapor phase growth apparatus in the present embodiment is similar to the first, second, and third embodiments, except that the vapor phase growth apparatus in the present embodiment includes a fourth manifold where first process gas, second process gas, and third process gas are mixed. Therefore, description of contents overlapping with the first, second, and third embodiments is omitted.

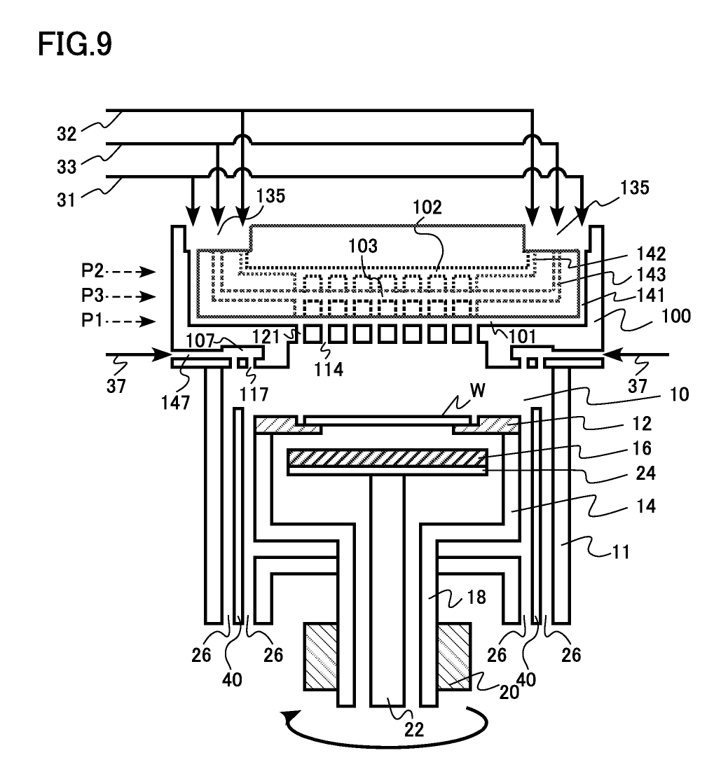

FIG. 9 is a schematic cross-sectional view of the vapor phase growth apparatus in the present embodiment.

In the present embodiment, first process gas supplied from the first gas supply passage 31, second process gas supplied from the second gas supply passage 32, and third process gas supplied from the third gas supply passage 33 are supplied to a fourth manifold 135. After the first process gas, the second process gas, and the third process gas are mixed in the fourth manifold, the mixed gas is supplied from the fourth gas ejection hole 114 to the reaction chamber. Accordingly, process gas can be mixed more uniformly.

According to the present embodiment, even in the case where, after gases composing process gas are mixed, the mixed gas is uniformly supplied onto a substrate W, the same effects as the first embodiment can be achieved. Furthermore, by providing sub purge gas supply passages like the second embodiment, the same effects as the second embodiment can be achieved.

As above, the embodiments of the present invention are described by reference to concrete examples. The above-described embodiments are just given as an example, and do not limit the invention. Furthermore, components of the embodiments can be appropriately combined.

For example, in the embodiments, the case where three systems of flow channels, such as the lateral gas flow channels, are provided is described as an example; however, four or more systems of flow channels, such as the lateral gas flow channels, can be provided, or two systems of flow channels can be provided.

Moreover, for example, in the embodiments, the case where a GaN (gallium nitride) single crystal film is formed is described as an example; however, the present invention can be also applied to the formation of an Si (silicon) or SiC (silicon carbide) single crystal film, etc.

Furthermore, in the embodiments, the single wafer type epitaxial apparatus that forms a film on one wafer is described as an example; however, the vapor phase growth apparatus is not limited to a single wafer type epitaxial apparatus. For example, the present invention can be also applied to a planetary type CVD apparatus or the like that simultaneously forms a film on a plurality of wafers that rotates or moves in orbit.

In the embodiments, description of parts not directly necessary for the description of the invention, such as the apparatus configuration and manufacturing method, is omitted; however, the needed apparatus configuration and manufacturing method, etc. can be appropriately selected and used. Besides these, all the vapor phase growth apparatuses and vapor phase growth methods that include elements of the present invention and those skilled in the art can make design changes thereof are included in the scope of the invention. The scope of the invention shall be defined by claims and the scopes of its equivalents.

What is claimed is:

1. A vapor phase growth apparatus comprising:
a reaction chamber;
a support provided in the reaction chamber, the support on which a substrate can be placed;
a first gas supply passage supplying first gas including ammonia;
a second gas supply passage supplying second gas including metal-organic gas;
a purge gas supply passage supplying purge gas including ammonia and at least one selected from nitrogen, hydrogen, and inert gas; and
a shower head including first region and second region provided around the first region, process gas ejection holes provided in the first region, connected to the first gas supply passage and second gas supply passage and through which the first gas and second gas are supplied into the reaction chamber, a purge gas ejection hole provided in the second region, connected to the purge gas supply passage and through which purge gas is supplied into the reaction chamber.

2. The vapor phase growth apparatus according to claim 1, wherein the process gas ejection holes include first gas ejection hole and second gas ejection hole, the first gas ejection hole connected to the first gas supply passage through a first lateral gas flow channel, the second gas ejection hole connected to the second gas supply passage through a second lateral gas flow channel.

3. The vapor phase growth apparatus according to claim 1, wherein the first gas and the second gas are mixed and supplied to the reaction chamber.

4. The vapor phase growth apparatus according to claim 1, wherein
when the second gas includes trimethylindium, the purge gas includes ammonia and nitrogen, and
when the second gas does not include trimethylindium, the purge gas includes ammonia, nitrogen, and hydrogen.

5. The vapor phase growth apparatus according to claim 2, further comprising:
a third gas supply passage supplying third gas for separating into the first gas and the second gas;
the process gas ejection holes further including a third gas ejection hole, the third gas ejection hole connected to the third gas supply passage through a third lateral gas flow channel.

6. The vapor phase growth apparatus according to claim 1, further comprising:
a third gas supply passage for supplying third gas for separating into the first gas and the second gas; and
a manifold where the first to third gases are supplied and mixed,
wherein the process gas ejection hole further includes a fourth gas ejection hole for supplying the first to third gases mixed in the manifold to the reaction chamber.

7. The vapor phase growth apparatus according to claim 1, further comprising a reflector provided around the support inside the reaction chamber.

8. The vapor phase growth apparatus according to claim 7, wherein the reflector is made of quartz.

9. A vapor phase growth method for forming a semiconductor film on a surface of a substrate, the vapor phase growth method comprising:
placing the substrate on a support provided in a reaction chamber;
heating the substrate; and
while supplying first gas including ammonia and second gas including metal-organic gas from an upper part of the reaction chamber onto the substrate, supplying purge gas including ammonia and at least one selected from nitrogen, hydrogen, and inert gas from the upper part of the reaction chamber to outside of the support along a side wall of the reaction chamber.
